(19) United States
(12) Patent Application Publication
(10) Pub. No.: US 2023/0262887 A1
(43) Pub. Date: Aug. 17, 2023

(54) CIRCUIT BOARD ASSEMBLY SYSTEM AND METHOD

(71) Applicant: Lear Corporation, Southfield, MI (US)

(72) Inventors: Luis Miguel Muñoz Garcia, Valls (ES); Carlos Ramon Borrego Garcia, Valls (ES); Joan Ignasi Ferran Palau, Valls (ES); Gloria Simo Quinonero, Valls (ES); Oscar Cano Salomo, Valls (ES); Victor Poblet-Espolet, Valls (ES)

(21) Appl. No.: 18/107,051

(22) Filed: Feb. 8, 2023

Related U.S. Application Data
(60) Provisional application No. 63/310,407, filed on Feb. 15, 2022.

(51) Int. Cl. H05K 1/02; H05K 3/34

(52) U.S. Cl. CPC H05K 1/0296; H05K 3/341; H05K 2201/10272

(57) ABSTRACT

An apparatus includes a circuit board and a plurality of bus bars fixed to the circuit board. The plurality of bus bars may include a first bus bar and a second bus bar formed from adjacent portions of a bus bar wire. The first bus bar may include a first bus bar first unplated portion and the second bus bar may include a second bus bar first unplated portion. The first bus bar first unplated portion and the second bus bar first unplated portion may be formed during formation of the first bus bar.

### CROSS-REFERENCE TO RELATED APPLICATION

This application claims the benefit of and priority to U.S. Provisional Patent Application Ser. No. 63/310,407, filed on Feb. 15, 2022, the disclosure of which is hereby incorporated by reference in its entirety as though fully set forth herein.

### TECHNICAL FIELD

The present disclosure generally relates to circuit board assembly systems and methods, including circuit board assembly systems and methods that may involve assembly lines.

### BRIEF DESCRIPTION OF THE DRAWINGS

While the claims are not limited to a specific illustration, an appreciation of various aspects may be gained through a discussion of various examples. The drawings are not necessarily to scale, and certain features may be exaggerated or hidden to better illustrate and explain an innovative aspect of an example. Further, the exemplary illustrations described herein are not exhaustive or otherwise limiting, and embodiments are not restricted to the precise form and configuration shown in the drawings or disclosed in the following detailed description. Exemplary illustrations are described in detail by referring to the drawings as follows:

FIG. 1 is a schematic view generally illustrating an embodiment of a circuit board assembly system according to teachings of the present disclosure.

FIG. 2 is a top view generally illustrating an embodiment of a circuit board with solder paste according to teachings of the present disclosure.

FIG. 3 is a perspective view generally illustrating an embodiment of a second machine of a circuit board assembly system according to teachings of the present disclosure.

FIG. 4 is a side view generally illustrating embodiments of bus bar wires of a circuit board assembly system according to teachings of the present disclosure.

FIG. 5 is a top view generally illustrating an embodiment of a circuit board with solder paste and bus bars according to teachings of the present disclosure.

FIG. 6 is a partial side view generally illustrating an embodiment of a circuit board with solder paste and a bus bar according to teachings of the present disclosure.

FIG. 7 is a top view generally illustrating an embodiment of a circuit board with solder paste, bus bars, and electrical components according to teachings of the present disclosure.

FIG. 8 is a partial side view generally illustrating an embodiment of a circuit board with solder paste and an electrical component according to teachings of the present disclosure.

FIG. 9 is a schematic view generally illustrating an embodiment of a circuit board assembly system according to teachings of the present disclosure.

FIG. 10 is a flow diagram view generally illustrating an embodiment of a circuit board assembly method according to teachings of the present disclosure.

### DETAILED DESCRIPTION

Reference will now be made in detail to embodiments, examples of which are illustrated in the accompanying drawings. In the following detailed description, numerous specific details are set forth in order to provide a thorough understanding of the various described embodiments. However, it will be apparent to one of ordinary skill in the art that the various described embodiments may be practiced without these specific details. In other instances, well-known methods, procedures, components, circuits, and networks have not been described in detail so as not to unnecessarily obscure aspects of the embodiments.

Some designs utilize preformed bus bars that may not allow for sufficient design and/or manufacturing flexibility, and/or may involve significant packaging costs. For example, preformed bus bars may come in a tape reel that has a mounting substrate (e.g., from which the bus bars are removed) and/or space between each bus bar. Such configurations may generate waste (e.g., the mounting substrate) and/or involve the use of additional reels as fewer bus bars may be provided from each reel. Additionally, preformed bus bars may involve a separate reel for each bus bar configuration (e.g., length, shape, etc.), which may generate additional waste and/or require additional space (e.g., in or near a machine). Some designs utilize bus bars that are connected to circuit boards via through-hole-technology (THT), such as via bus bar staples. THT designs may involve additional assembly steps of forming and placing the staples and/or pressing the staples into a circuit board, which may involve relatively large machines to provide sufficient insertion force and/or components to limit stress applied to the circuit board.

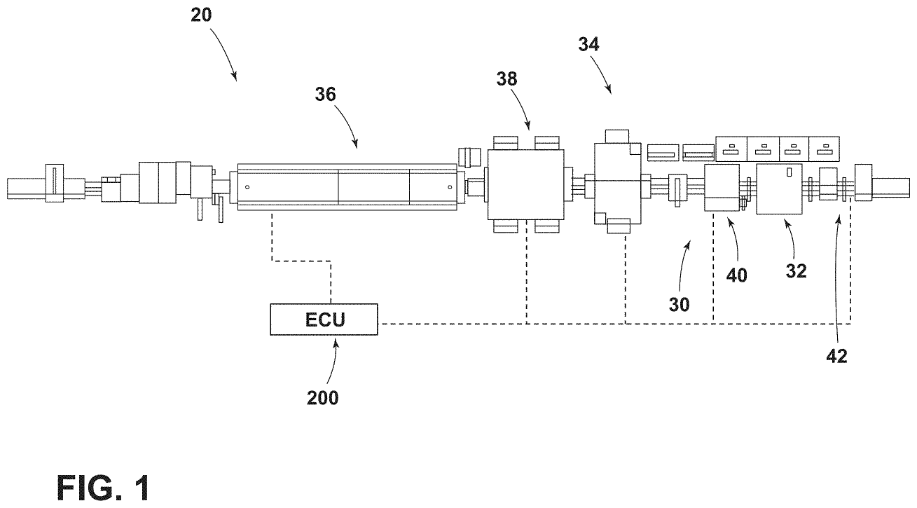

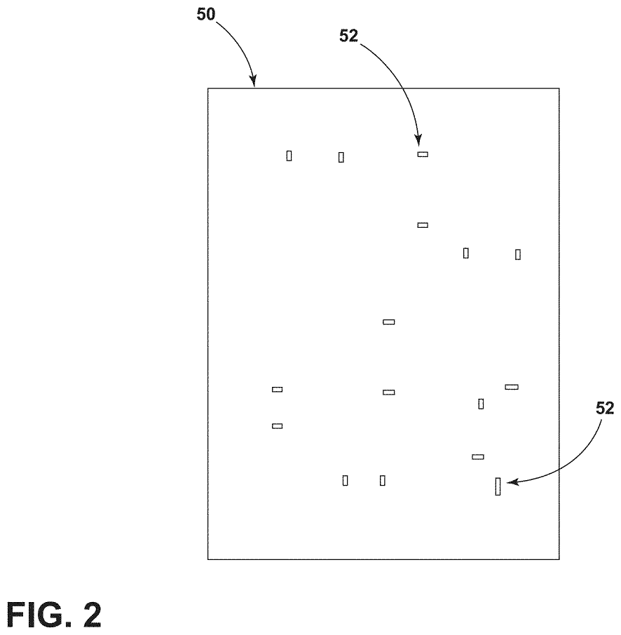

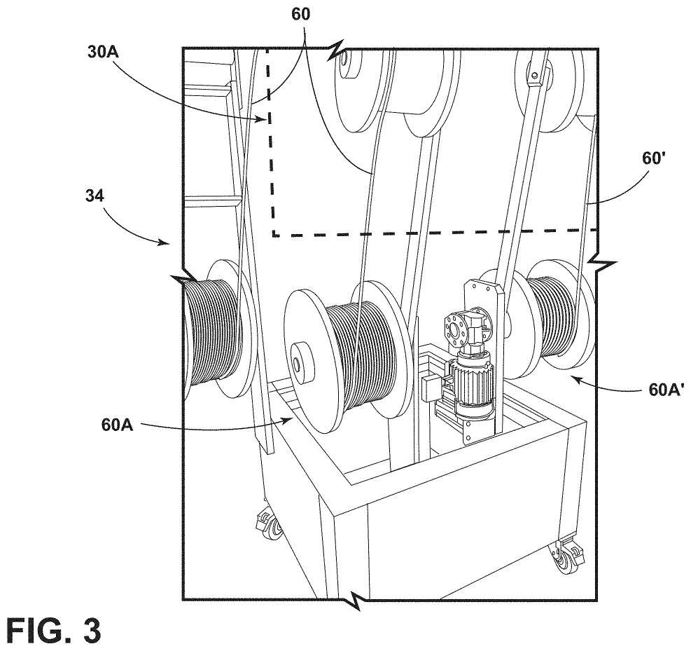

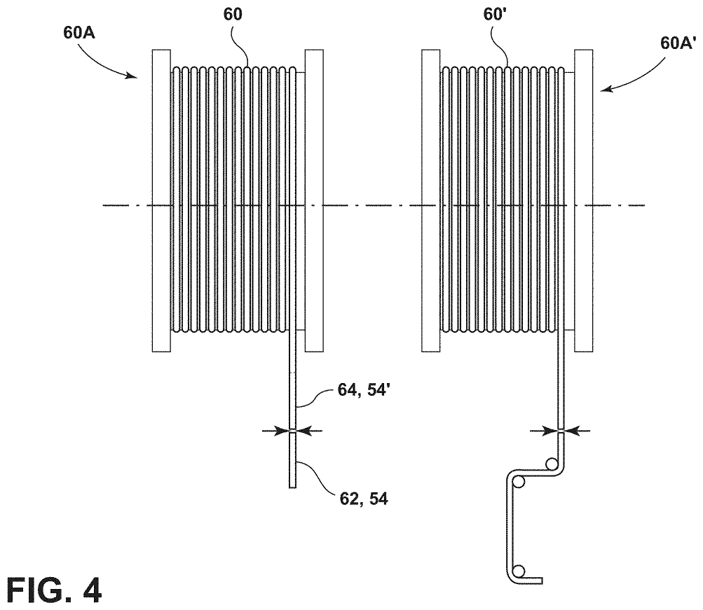

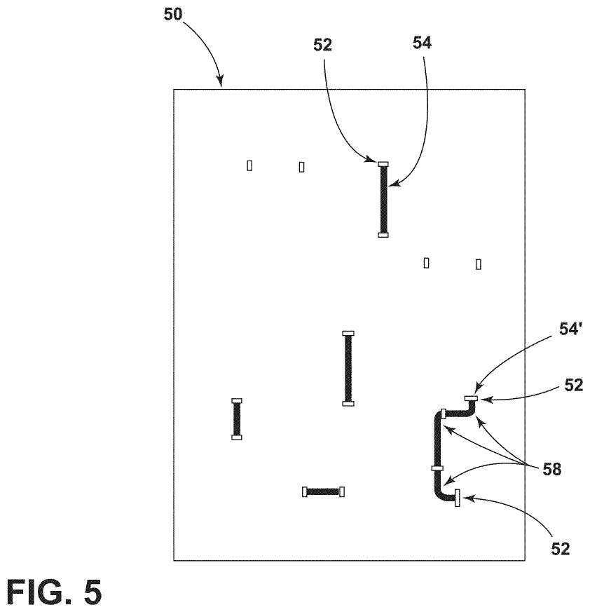

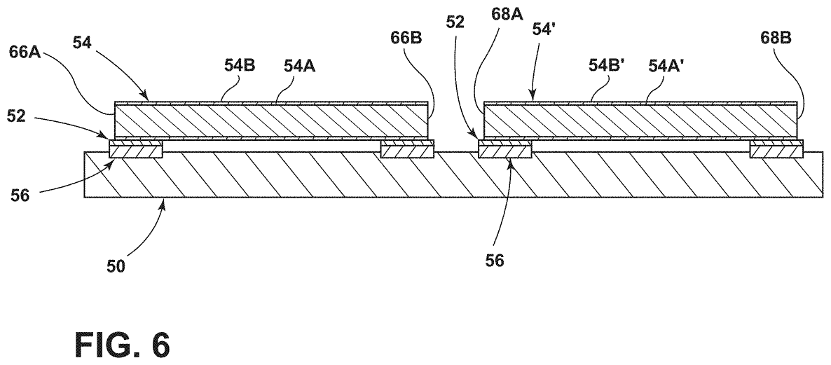

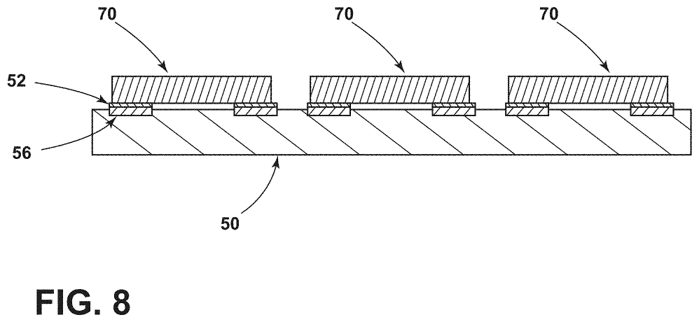

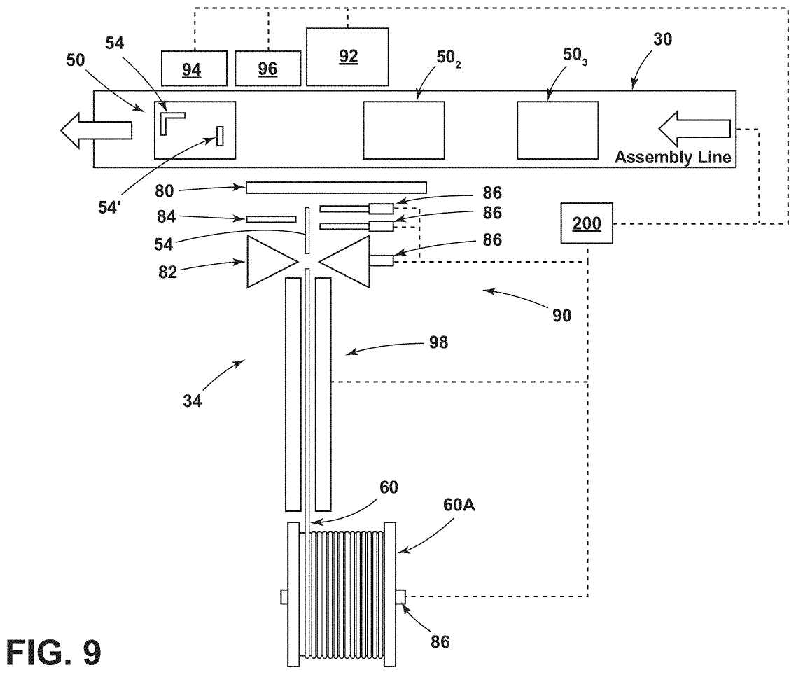

In embodiments, such as generally illustrated in FIG. 1, a circuit board assembly system 20 may include an assembly line 30, which may include one or more machines, such as a first machine 32, a second machine 34, a third machine 36, a fourth machine 38, a fifth machine 40, and/or one or more other machines. The first machine 32 may, for example and without limitation, include a solder applicator/application machine that may be configured to apply solder 52 (e.g., solder paste and/or solder pads) to circuit boards 50 (see, e.g., FIG. 2). In some instances, a circuit board 50 may include one or more solder pads 56 (see, e.g., FIGS. 6 and 8) and at least some of the solder/solder paste 52 may be applied to the one or more solder pads 56. As generally illustrated in FIG. 9, the second machine 34 may, for example and without limitation, include a bus bar machine that may be configured to form bus bars 54 (e.g., surface mount device (SMD) bus bars), such as from one or more bus bar wires 60, 60′ (see, e.g., FIGS. 3 and 4) and/or place bus bars 54 on a circuit board 50 and/or solder/solder paste 52 thereof (see, e.g., FIGS. 5 and 6). The one or more bus bar wires 60, 60′ may, for example and without limitation, may be provided as raw wire reels 60A, 60A′ that may include different wire material, plating, and/or cross-sectional size and/or cross-sectional shape. A wall 30A of the assembly line 30 may be disposed between the reels 60A, 60A′ and the conveyor system 42 (see, e.g., FIG. 3). The bus bar wires 60, 60′ may extend over the wall 30A, such as into other portions of a second machine 34.

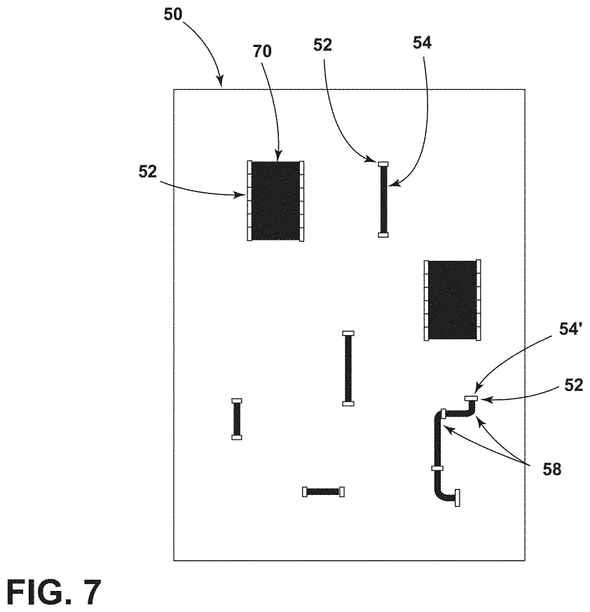

In embodiments, the third machine 36 may, for example and without limitation, include a soldering machine, such as reflow soldering oven, that may be configured to solder bus bars 54 and/or other electrical components 70 to circuit boards 50, such as by heating the solder/solder paste 52. The fourth machine 38 may, for example and without limitation, include one or more pick-and-place machines/robots that may be configured to place electrical components 70 on a circuit board 50 and/or solder/solder paste 52 thereof (see, e.g., FIGS. 7 and 8). For example, the fourth machine 38 may include a plurality of machines/robots to place a large quantity of components 70 more quickly and/or to place components 70 of significantly different sizes. The fifth machine 40 may be configured to conduct an inspection of solder/solder paste 52 applied to the circuit board 50 (e.g., via the first machine 32). For example, the fifth machine 40 may conduct an optical inspection, such as via one or more cameras or other optical devices.

In embodiments, the second machine 34 may be disposed between the first machine 32 and the third machine 36 along the assembly line 30, and/or between the first machine 32 and the fourth machine 38. The fourth machine 38 may be disposed between the second machine 34 and the third machine 36. The second machine 34 may be disposed adjacent (e.g., after, in an assembly direction) to the first machine 32 or a fifth machine, and/or adjacent (e.g., before, in an assembly direction) the third machine 36 or the fourth machine 38. In some configurations, a fourth machine 38 may be disposed before a second machine 34 along an assembly line 30. In some instances, a system 20 may include one or more machines for inserting THT components, such as THT connectors or relays, that may be configured for reflow oven temperatures. If THT components are to be inserted, solder/solder paste 52 may be applied according to pin-in-paste technology specifications. Additionally or alternatively, THT components may be added/inserted via a machine disposed after the third machine or at a different assembly line, which may be configured for wave soldering the THT components.

In embodiments, the assembly line 30 may include a conveyor system 42 that may extend into, through, and/or adjacent to the first machine 32, the second machine 34, the third machine 36, the fourth machine 38, the fifth machine 40, and/or one or more other machines (see, e.g., FIG. 1). For example and without limitation, the conveyor system 42 may extend through the first machine 32, the fifth machine 40, the second machine 34, the fourth machine 38, and/or the third machine 36 (e.g., in a straight line) to move circuit boards 50 and/or bus bars/components 54, 70 connected thereto along the assembly line 30.

In some configurations, a machine 32-40 may include one or more machine portions that may be configured to conduct various actions and that may or may not be independent of each other. For example and without limitation, a second machine 34 may include a first portion 90 that forms a bus bar 54, a second portion 92 (e.g., one or more movable armatures and/or robotic arms) that disposes bus bars 54 on a circuit board 50, a third portion 94 with one or more sensors for optical inspection, and/or a fourth portion 96 (e.g., a fan, a pump, and/or connection to an external source of compressed air) that blows air away from circuit board 50, among other possible portions (see, e.g., FIG. 9). A first portion 90 of the second machine 34 may, for example, include a blade and/or saw 82 for cutting bus bars 54, and/or one or more bending dies/presses 84 for bending bus bars 54. The second machine 34 may include one or more actuators 86 (e.g., motors, cylinders, presses, etc.) that actuate elements of the first portion 90, such as a blade/saw 82, and/or one or more bending dies/presses 84. The first portion 90 may include a feeder line 98 that may be disposed between the reel(s) 60A, 60A′ and a blade/saw 82, and may align and/or push a wire 60, 60′ toward the blade/saw 82. For example, the feeder line 98 may feed a wire 60, 60′ according to the desired length of a bus bar 54, 54′. The feeder line 98 may be at an oblique or right angle to the assembly line 30.

In some embodiments, one or more machines 32-40 may include common portions and/or may be at least partially integrated with each other. Additionally or alternatively, one or more machines 32-40 may be separate from other machines 32-40.

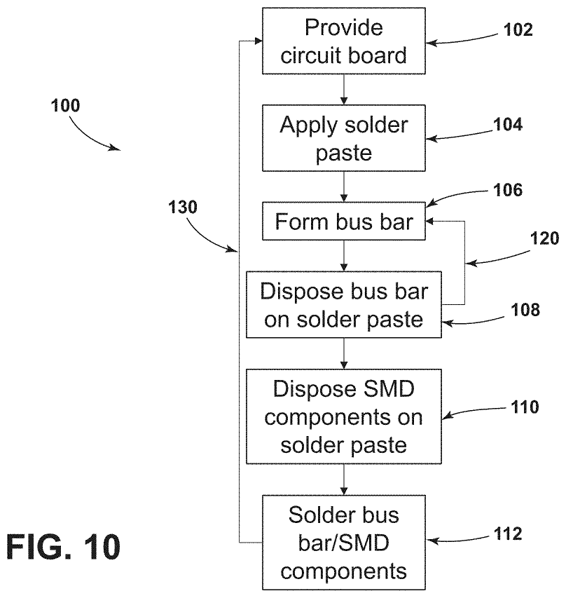

With embodiments, such as generally illustrated in FIG. 10, a circuit board assembly method 100 may include providing a circuit board 50 (block 102). The method 100 may include applying solder/solder paste 52 to the circuit board 50 (block 104), such as via a first machine 32. Applying the solder/solder paste 52 to the circuit board 50 may include a conveyor system 42 of an assembly line 30 moving the circuit board 50 toward, into, and/or through the first machine 32. The solder/solder paste 52 may be applied to a plurality of locations on the circuit board 50 and may be applied in a plurality of shapes and/or onto solder pads 56 of the circuit board 50.

In embodiments, the method 100 may include forming a bus bar 54 (block 106), such as via a second machine 34. Forming the bus bar 54 may include cutting the bus bar 54, such as from one or more bus bar wires 60, 60′ via one or more blades/saws 82, and/or shaping the bus bar 54. Shaping the bus bar 54 may include the second machine 34 bending the bus bar 54 via one or more bending dies/presses 84 such that the bus bar 54 includes one or more bends 58. The one or more bends 58 may include bends of various angles, such as acute angles, right angles, and/or obtuse angles (see, e.g., FIGS. 5 and 7). In some configurations, a bus bar 54 may be bent from a wire 60, 60′ prior to a final cut to remove the bus bar 54 from the wire, which may facilitate fixation. The one or more bends 58 may be formed such that the bus bar 54 is substantially parallel with a single plane (e.g., parallel to the circuit board 50) or may be formed such that at least some portions of the bus bar 54 are disposed at one or more oblique or right angles relative to the circuit board 50. For example, bus bars 54 may be formed to extend over already placed components (e.g., like a bridge), such as via one or more bending dies/presses that may be disposed and/or may move parallel to a vertical direction. In some configurations, a bus bar 54 may be formed with one or more rounded or round portions (e.g., with respective curvature radii). The second machine 34 may be configured to form/cut bus bars 54 of different lengths. In some instances, a bus bar 54 may be formed via a first bus bar wire 60 and one or more additional bus bar wires 60′, such as to provide a bus bar 54 with increased width and/or thickness/height. A bus bar 54 may be formed with one or more of a variety of cross-sectional shapes, such as rectangular, square, round, oval-shaped, and/or triangular, among others. Bus bars 54 may be tinned/plated after formation, such as to facilitate soldering, and/or the bus bare wires 60, 60′ may be pre-tinned/plated.

In some embodiments, with pre-plated bus bar wires 60, 60′, forming bus bars 54, 54′ may result in at least a portion of a core 54A, 54A′ of a bus bar 54, 54′ being exposed (e.g., not covered by plating 54B, 54B′), such as when cutting the bus bars 54, 54′ from the wires (see, e.g., FIG. 6).

With embodiments, the method 100 may include disposing the formed bus bar 54 on the circuit board 50 and/or on the solder/solder paste 52 thereon (block 108), such as via the second machine 34 and/or another machine. For example and without limitation, the second machine 34 may include a second portion 92 (e.g., a pick-and-place portion) that may include one or more movable armatures and/or robots. Disposing a bus bar 54 (block 108) may, in some configurations, include conducting an optical inspection via an optical inspection system (e.g., an automatic optical inspection system), which may be included with a third portion 94 of the second machine 34 and/or another machine, such as to confirm the correct placement of some or each of the bus bars 54 on a circuit board 50.

In embodiments, the method 100 may include disposing one or more electrical components 70 on the circuit board 50 and/or on the solder/solder paste 52 thereon (block 110), such as via the fourth machine 38 and/or another machine. The fourth machine 38 may, for example and without limitation, include a pick-and-place machine and/or robot. The one or more electrical components 70 may, for example, include SMDs, such as chips/integrated circuits, operational amplifiers, fuses, resistors, capacitors, inductors, transistors, and/or diodes, among others. Disposing one or more electrical components 70 may include the conveyor system 42 moving the circuit board 50, such as from the second machine 34 to the fourth machine 38. As the circuit board 50 moves from the second machine 34 to the fourth machine 38, solder/solder paste 52 may already be disposed on the circuit board 50 and one or more bus bars 54 may be in contact with the circuit board 50 and/or the solder/solder paste 52. In some configurations, block 110 may occur before block 106 and/or may occur before and after blocks 106, 108.

With embodiments, the method 100 may include soldering one or more bus bars 54 with the circuit board 50 (block 112), such as via the third machine 36. One or more electrical components 70 may be soldered with the circuit board 50 at or about the same time as the one or more bus bars 54 (e.g., the third machine 36 may simultaneously solder one or more bus bars 54 and one or more electrical components 70 with the circuit board 50). Soldering one or more bus bars 54 may include the conveyor system 42 moving the circuit board 50, such as from the fourth machine 38 to the third machine 36. As the circuit board 50 moves from the fourth machine 38 to the third machine 36, solder/solder paste 52 may already be disposed on the circuit board 50 and one or more bus bars 54 and/or one or more electrical components 70 may be in contact with the circuit board 50 and/or the solder/solder paste 52. In some configurations, the system 20 may not include a fourth machine 38 and/or the conveyor system 42 may move the circuit board 50 from the second machine 34 to the third machine 36 (e.g., directly).

In embodiments, the method 100 may include forming one or more additional bus bars 54′ for connection with a circuit board 50. For example, the method 100 may include forming a first bus bar 54 in block 106, disposing the first bus bar 54 on the circuit board 50 in block 108, forming a second bus bar 54′, such as by repeating block 106, and/or disposing the second bus bar 54′ on the circuit board 50, such as via repeating block 108 (see, e.g., arrow 120). In some configurations, the second bus bar 54′ may be formed, at least in part, while the first bus bar 54 is being disposed or is already disposed on the circuit board 50 and prior to the bus bar 54 being soldered. The second bus bar 54′ may or may not include a different length and/or shape than the first bus bar 54.

In some configurations, a plurality of bus bars 54 with different lengths and/or shapes may be formed for and placed on the same circuit board 50. In some instances, a first bus bar 54 and a second bus bar 54′ may be formed from adjacent portions 62, 64 of a bus bar wire 60 (see, e.g., FIG. 4). Removing a portion 62, 64 from a bus bar wire 60 may involve a cutting operation that separates a second end of the bus bar 54 from a first end of the bus bar 54′. The cutting operation, in some instances, including exposing a core 54A, 54A′ from one or both of the bus bars 54, 54′, which may result in one or both bus bars 54, 54′ having unplated or bare portions of a core 54A. 54A′. For example and without limitation, a first bus bar 54 may include an unplated portion 66B and a second bus bar 54′ may include an unplated portion 68A that may be formed (e.g., simultaneously) during formation of the first bus bar 54 (see, e.g., FIG. 6). The first bus bar 54 may include another unplated portion 66A that may have been formed during formation of a prior bus bar. The second bus bar may include another unplated portion 68B that may be formed during formation of a subsequent/third bus bar. For example, with plated wires 60, 60′, each bus bar 54, 54′ may include a first unplated portion and a second unplated portion that are disposed at respective ends of the bus bar 54, 54′ and that are formed during separation of the bus bar 54, 54′ from adjacent portions of the wire 60, 60′. Unplated portions may include portions of a core 54A, 54A′ that are not covered by plating 54B, 54B′.

With embodiments, the method 100 may include assembling a second circuit board assembly and/or one or more additional circuit board assemblies, such as by repeating blocks 102, 104, 106, 108, 110, and/or 112 (see, e.g., arrow 130). A second circuit board assembly may generally resemble that shown in FIG. 7 and may include the same or different configurations of solder/solder paste 52, bus bars 54, and/or electrical components 70 In some instances, bus bars 54 for the second circuit board assembly may be formed, at least in part, while one or more electrical components 70 are disposed on the first circuit board 50. A second circuit board assembly may include a second circuit board 502 and/or an additional circuit board assembly may include an additional circuit board 503 (see, e.g., FIG. 9).

In embodiments, the second machine 34 may include a shield 80 that may be configured to limit movement of bus bar particles (e.g., shavings, dust, etc. from a cutting or sawing operation) that may be formed from a bus bar wire 60, 60′ during formation of bus bars 54 (see, e.g., FIG. 9). For example, the shield 80 may be configured to restrict particles from reaching the solder/solder paste 52 of the current circuit board 50 (e.g., the circuit board to which the bus bar 54 will be connected), one or more prior circuit boards, and/or one or more following circuit boards. In some configurations, the second machine 34 may form bus bars 54 proximate a circuit board 50. For example and without limitation, the bus bars 54 may be formed within about three feet/one meter of a circuit board 50 that may already have solder paste 52 applied to it. In some configurations, forming of a bus bar 54 may be conducted at a low height (e.g., below a level of circuit boards 50 on the conveyor system 42), which may limit particle movement and/or improve the effectiveness of a shield 80. Additionally or alternatively, a fourth portion 96 of the the second machine 34 may be configured to provide a flow of air away from the conveyor system 42 and/or the circuit boards 50 (e.g., the second machine 34 may include and/or be connected to a fan and/or a pump).

In systems that do not utilize SMD bus bars, particles may be removed from a circuit board via the application of air (e.g., a fan, sprayer, etc.) directly to the circuit board. However, as circuit boards 50 of embodiments of the system 20 may include un-soldered solder/solder paste 52, such particles may stick to the solder/solder paste 52 such that they are not readily removable from the circuit board 50 via the application of air. The shield 80 may prevent and/or limit the particles that reach a circuit board 50, even though the bus bars 54 may be formed proximate the circuit board 50.

With embodiments, circuit board assemblies (e.g., circuit boards 50, 502, 503 with one or more bus bars 54 and/or one or more electrical components 70 fixed thereto) may be formed via soldering, such as without the use of separate fasteners, such as staples or screws, and may or may not include THT components. In some configurations, the bus bars 54 and/or the electrical components 70 may not be inserted into the circuit board 50 and may not extend into or through the circuit board 50.

With embodiments, a system 20 may include an electronic control unit (ECU) 200. The ECU 200 may be connected to (e.g., via wired and/or wireless connection) and/or configured to control, at least in part, one or more of the assembly line 30, the first machine 32, the second machine 34, the third machine 36, the fourth machine 38, and/or the conveyor system 42. For example and without limitation, the ECU 200 may be configured to operate the conveyor system 42 to move circuit boards 50 to the machines 32-40 and/or to operate the respective machines 32-40 to assemble a circuit board assembly. The ECU 200 may, for example, control, at least in part, operation of a first portion 90 (e.g., one or more blades/saws 82, one or more bending dies/presses 84, one or more actuators 86), a second portion 92, a third portion 94, and/or a fourth portion 96 of a second machine 34.

In embodiments, formed bus bars 54 may be disposed in substantially the same three-dimensional location relative to the assembly line 30, which may facilitate picking up of the bus bars 54 by the second machine 34 (e.g., the second portion 92 and/or an arm/armature thereof). In contrast, with reels of preformed bus bars, especially longer bus bars, the location of the preformed bus bar may vary, which may make picking up of the bus bars more challenging (e.g., less accurate/consistent, more time consuming, etc.).

The instant disclosure includes the following nonlimiting embodiments:

1. An apparatus, comprising: a circuit board; and a plurality of bus bars fixed to the circuit board; wherein the plurality of bus bars includes a first bus bar and a second bus bar formed from adjacent portions of a bus bar wire.

2. The apparatus according to embodiment 1, wherein the first bus bar includes a first bus bar first unplated portion and the second bus bar includes a second bus bar first unplated portion, the first bus bar first unplated portion and the second bus bar first unplated portion formed during formation of the first bus bar.

3. The apparatus according to any preceding embodiment, wherein the first bus bar and the second bus bar are surface mounted and do not extend into or through the circuit board.

4. The apparatus according to any preceding embodiment, wherein the first bus bar and the second bus bar are not fixed to the circuit board via a fastener (e.g., the bus bars may be soldered with the circuit board without separate/discrete fasteners).

5. The apparatus according to any preceding embodiment, wherein the second bus bar has a different length and/or a different shape than the first bus bar.

6. A method of assembling the apparatus according to any preceding embodiment, the method comprising: applying solder paste to the circuit board; forming the first bus bar from the bus bar wire; disposing the first bus bar on the solder paste on the circuit board; forming the second bus bar from the bus bar wire; disposing the second bus bar on the solder paste on the circuit board; and soldering the first bus bar and the second bus bar with the circuit board.

7. The method of embodiment 6, comprising disposing a plurality of electronic devices on the solder paste; wherein the plurality of electronic devices are soldered with the circuit board as the plurality of bus bars are soldered with the circuit board.

8. The method according to any of embodiments 6-7, wherein forming the first bus bar and the second bus bar includes cutting the first bus bar and the second bus bar from the bus bar wire.

9. The method according to any of embodiments 6-8, wherein forming the first bus bar includes bending the first bus bar.

10. The method according to any of embodiments 6-9, including forming a third bus bar from a second bus bar wire having a different material and/or cross-section than the bus bar wire.

11. The method according to any of embodiments 6-10, wherein cutting the first bus bar exposes a core of the first bus bar and a core of the second bus bar.

12. The method according to any of embodiments 6-11, wherein the solder paste is applied to the circuit board via a first machine of an assembly line; the first bus bar and the second bus bar are formed via a second machine of the assembly line; the first bus bar and the second bus bar are disposed on the solder paste via the second machine of the assembly line; and the first bus bar and the second bus bar are soldered via a reflow soldering oven of the assembly line.

13. The method according to any of embodiments 6-12, wherein the second machine is disposed between the first machine and the reflow soldering oven along the assembly line.

14. The method according to any of embodiments 6-13, wherein the second machine includes a shield that restricts movement of particles from the bus bar wire during formation of the plurality of bus bars.

15. The method according to any of embodiments 6-14, comprising: applying solder paste to a second circuit board; forming a second circuit board first bus bar from the bus bar wire; disposing the second circuit board first bus bar on the solder paste on the second circuit board; and soldering the second circuit board first bus bar with the second circuit board.

16. The method according to any of embodiments 6-16, wherein the second circuit board first bus bar is formed, at least in part, while the plurality of bus bars are disposed on the solder paste and before the plurality of bus bars are soldered.

17. An apparatus, comprising: a circuit board; and a bus bar fixed to the circuit board, the bus bar including a first end and a second end; wherein the bus bar is plated; the first end includes a first unplated portion; and the second end includes a second unplated portion.

18. The apparatus according to embodiment 17, wherein the first unplated portion is formed via separation of the bus bar from a first adjacent portion of a bus bar wire; and the second unplated portion is formed via separation of the bus bar from a second adjacent portion of the bus bar wire.

19. The apparatus according to embodiment 17 or 18, including a second bus bar fixed to the circuit board;

wherein the second bus bar is formed from the second adjacent portion of the bus bar wire.

20. A method of assembling the apparatus according to any of embodiment 17-19, the method comprising: applying solder paste to the circuit board; forming the bus bar from a bus bar wire; and disposing the bus bar on the solder paste on the circuit board; wherein forming the bus bar includes cutting the bus bar from an adjacent portion of the bus bar wire; and cutting the bus bar from the adjacent portion exposes a core of the bus bar to provide the first unplated portion or the second unplated portion.

21. The apparatus or method according to any preceding embodiment, wherein the first bus bar has a round cross-section.

22. The apparatus or method according to any preceding embodiment, wherein the first bus bar has a rectangular cross-section.

23. The apparatus or method according to any preceding embodiment, wherein the second bus bar has a different length than the first bus bar.

24. The apparatus or method according to any preceding embodiment, wherein the second bus bar has a different shape than the first bus bar.

In examples, an ECU (e.g., ECU 200) may include an electronic controller and/or include an electronic processor, such as a programmable microprocessor and/or microcontroller. In embodiments, an ECU may include, for example, an application specific integrated circuit (ASIC). An ECU may include a central processing unit (CPU), a memory (e.g., a non-transitory computer-readable storage medium), and/or an input/output (I/O) interface. An ECU may be configured to perform various functions, including those described in greater detail herein, with appropriate programming instructions and/or code embodied in software, hardware, and/or other medium. In embodiments, an ECU may include a plurality of controllers. In embodiments, an ECU may be connected to a display, such as a touchscreen display.

Various examples/embodiments are described herein for various apparatuses, systems, and/or methods. Numerous specific details are set forth to provide a thorough understanding of the overall structure, function, manufacture, and use of the examples/embodiments as described in the specification and illustrated in the accompanying drawings. It will be understood by those skilled in the art, however, that the examples/embodiments may be practiced without such specific details. In other instances, well-known operations, components, and elements have not been described in detail so as not to obscure the examples/embodiments described in the specification. Those of ordinary skill in the art will understand that the examples/embodiments described and illustrated herein are non-limiting examples, and thus it can be appreciated that the specific structural and functional details disclosed herein may be representative and do not necessarily limit the scope of the embodiments.

Reference throughout the specification to “examples, “in examples,” “with examples,” “various embodiments,” “with embodiments,” “in embodiments,” or “an embodiment,” or the like, means that a particular feature, structure, or characteristic described in connection with the example/embodiment is included in at least one embodiment. Thus, appearances of the phrases “examples, “in examples,” “with examples,” “in various embodiments,” “with embodiments,” “in embodiments,” or “an embodiment,” or the like, in places throughout the specification are not necessarily all referring to the same embodiment. Furthermore, the particular features, structures, or characteristics may be combined in any suitable manner in one or more examples/embodiments. Thus, the particular features, structures, or characteristics illustrated or described in connection with one embodiment/example may be combined, in whole or in part, with the features, structures, functions, and/or characteristics of one or more other embodiments/examples without limitation given that such combination is not illogical or non-functional. Moreover, many modifications may be made to adapt a particular situation or material to the teachings of the present disclosure without departing from the scope thereof.

It should be understood that references to a single element are not necessarily so limited and may include one or more of such element. Any directional references (e.g., plus, minus, upper, lower, upward, downward, left, right, leftward, rightward, top, bottom, above, below, vertical, horizontal, clockwise, and counterclockwise) are only used for identification purposes to aid the reader's understanding of the present disclosure, and do not create limitations, particularly as to the position, orientation, or use of examples/embodiments.

“One or more” includes a function being performed by one element, a function being performed by more than one element, e.g., in a distributed fashion, several functions being performed by one element, several functions being performed by several elements, or any combination of the above.

It will also be understood that, although the terms first, second, etc. are, in some instances, used herein to describe various elements, these elements should not be limited by these terms. These terms are only used to distinguish one element from another. For example, a first element could be termed a second element, and, similarly, a second element could be termed a first element, without departing from the scope of the various described embodiments. The first element and the second element are both element, but they are not the same element.

The terminology used in the description of the various described embodiments herein is for the purpose of describing particular embodiments only and is not intended to be limiting. As used in the description of the various described embodiments and the appended claims, the singular forms “a”, “an” and “the” are intended to include the plural forms as well, unless the context clearly indicates otherwise. It will also be understood that the term “and/or” as used herein refers to and encompasses any and all possible combinations of one or more of the associated listed items. It will be further understood that the terms “includes,” “including,” “comprises,” and/or “comprising,” when used in this specification, specify the presence of stated features, integers, steps, operations, elements, and/or components, but do not preclude the presence or addition of one or more other features, integers, steps, operations, elements, components, and/or groups thereof.

Joinder references (e.g., attached, coupled, connected, and the like) are to be construed broadly and may include intermediate members between a connection of elements, relative movement between elements, direct connections, indirect connections, fixed connections, movable connections, operative connections, indirect contact, and/or direct contact. As such, joinder references do not necessarily imply that two elements are directly connected/coupled and in fixed relation to each other. Connections of electrical components, if any, may include mechanical connections, electrical connections, wired connections, and/or wireless connections, among others. Uses of “e.g.” and “such as” in the specification are to be construed broadly and are used to provide non-limiting examples of embodiments of the disclosure, and the disclosure is not limited to such examples.

While processes, systems, and methods may be described herein in connection with one or more steps in a particular sequence, it should be understood that such methods may be practiced with the steps in a different order, with certain steps performed simultaneously, with additional steps, and/or with certain described steps omitted.

As used herein, the term “if” is, optionally, construed to mean “when” or “upon” or “in response to determining” or “in response to detecting,” depending on the context. Similarly, the phrase “if it is determined” or “if [a stated condition or event] is detected” is, optionally, construed to mean “upon determining” or “in response to determining” or “upon detecting [the stated condition or event]” or “in response to detecting [the stated condition or event],” depending on the context.

All matter contained in the above description or shown in the accompanying drawings shall be interpreted as illustrative only and not limiting. Changes in detail or structure may be made without departing from the present disclosure.

It should be understood that a computer/computing device, an electronic control unit (ECU), a system, and/or a processor as described herein may include a conventional processing apparatus known in the art, which may be capable of executing preprogrammed instructions stored in an associated memory, all performing in accordance with the functionality described herein. To the extent that the methods described herein are embodied in software, the resulting software can be stored in an associated memory and can also constitute means for performing such methods. Such a system or processor may further be of the type having ROM, RAM, RAM and ROM, and/or a combination of non-volatile and volatile memory so that any software may be stored and yet allow storage and processing of dynamically produced data and/or signals.

It should be further understood that an article of manufacture in accordance with this disclosure may include a non-transitory computer-readable storage medium having a computer program encoded thereon for implementing logic and other functionality described herein. The computer program may include code to perform one or more of the methods disclosed herein. Such embodiments may be configured to execute via one or more processors, such as multiple processors that are integrated into a single system or are distributed over and connected together through a communications network, and the communications network may be wired and/or wireless. Code for implementing one or more of the features described in connection with one or more embodiments may, when executed by a processor, cause a plurality of transistors to change from a first state to a second state. A specific pattern of change (e.g., which transistors change state and which transistors do not), may be dictated, at least partially, by the logic and/or code.

What is claimed is:

1. An apparatus, comprising:
a circuit board; and
a plurality of bus bars fixed to the circuit board;
wherein the plurality of bus bars includes a first bus bar and a second bus bar formed from adjacent portions of a bus bar wire.

2. The apparatus of claim 1, wherein the first bus bar includes a first bus bar first unplated portion and the second bus bar includes a second bus bar first unplated portion, the first bus bar first unplated portion and the second bus bar first unplated portion formed during formation of the first bus bar.

3. The apparatus of claim 1, wherein the first bus bar and the second bus bar are surface mounted and do not extend into or through the circuit board.

4. The apparatus of claim 1, wherein the first bus bar and the second bus bar are not fixed to the circuit board via a fastener.

5. The apparatus of claim 1, wherein the second bus bar has a different length and/or a different shape than the first bus bar.

6. A method of assembling the apparatus of claim 1, the method comprising:
applying solder paste to the circuit board;
forming the first bus bar from the bus bar wire;
disposing the first bus bar on the solder paste on the circuit board;
forming the second bus bar from the bus bar wire;
disposing the second bus bar on the solder paste on the circuit board; and
soldering the first bus bar and the second bus bar with the circuit board.

7. The method of claim 6, comprising disposing a plurality of electronic devices on the solder paste;
wherein the plurality of electronic devices are soldered with the circuit board as the plurality of bus bars are soldered with the circuit board.

8. The method of claim 6, wherein forming the first bus bar and the second bus bar includes cutting the first bus bar and the second bus bar from the bus bar wire.

9. The method of claim 8, wherein forming the first bus bar includes bending the first bus bar.

10. The method of claim 8, including forming a third bus bar from a second bus bar wire having a different material and/or cross-section than the bus bar wire.

11. The method of claim 8, wherein cutting the first bus bar exposes a core of the first bus bar and a core of the second bus bar.

12. The method of claim 6, wherein the solder paste is applied to the circuit board via a first machine of an assembly line;
the first bus bar and the second bus bar are formed via a second machine of the assembly line;
the first bus bar and the second bus bar are disposed on the solder paste via the second machine of the assembly line; and
the first bus bar and the second bus bar are soldered via a reflow soldering oven of the assembly line.

13. The method of claim 12, wherein the second machine is disposed between the first machine and the reflow soldering oven along the assembly line.

14. The method of claim 12, wherein the second machine includes a shield that restricts movement of particles from the bus bar wire during formation of the plurality of bus bars.

15. The method of claim 6, comprising:
applying solder paste to a second circuit board;
forming a second circuit board first bus bar from the bus bar wire;
disposing the second circuit board first bus bar on the solder paste on the second circuit board; and
soldering the second circuit board first bus bar with the second circuit board.

16. The method of claim 15, wherein the second circuit board first bus bar is formed, at least in part, while the plurality of bus bars are disposed on the solder paste and before the plurality of bus bars are soldered.

17. An apparatus, comprising:
a circuit board; and
a bus bar fixed to the circuit board, the bus bar including a first end and a second end;
wherein the bus bar is plated;
the first end includes a first unplated portion; and
the second end includes a second unplated portion.

18. The apparatus of claim 17, wherein the first unplated portion is formed via separation of the bus bar from a first adjacent portion of a bus bar wire; and
the second unplated portion is formed via separation of the bus bar from a second adjacent portion of the bus bar wire.

19. The apparatus of claim 18, including a second bus bar fixed to the circuit board;
wherein the second bus bar is formed from the second adjacent portion of the bus bar wire.

20. A method of assembling the apparatus of claim 17, the method comprising:
applying solder paste to the circuit board;
forming the bus bar from a bus bar wire; and
disposing the bus bar on the solder paste on the circuit board;
wherein forming the bus bar includes cutting the bus bar from an adjacent portion of the bus bar wire; and
cutting the bus bar from the adjacent portion exposes a core of the bus bar to provide the first unplated portion or the second unplated portion.
